(19) United States
(12) Patent Application Publication
(10) Pub. No.: US 2025/0155640 A1
(43) Pub. Date: May 15, 2025

(54) PHOTONIC DEVICE AND METHOD

(71) Applicant: STMicroelectronics International N.V., Geneva (CH)

(72) Inventors: Sébastien Cremer, Sassenage (FR); Frédéric Boeuf, St Nazaire les Eymes (FR)

(21) Appl. No.: 18/922,884

(22) Filed: Oct. 22, 2024

(30) Foreign Application Priority Data
Nov. 9, 2023 (FR) 2312182

(51) Int. Cl. G02B 6/13

(52) U.S. Cl. CPC G02B 6/13

(57) ABSTRACT

A method of manufacturing a photonic device comprises, successively, forming on a first substrate at least one metallization level and a first bonding layer, forming on a second high-resistivity substrate a second bonding layer, bonding the first bonding layer to the second bonding layer, removing the first substrate; and forming a first optical component on the at least one metallization level. A sum of the thicknesses of the first and second bonding layers and of the thickness of the at least one metallization level is greater than 3 μm.

### CROSS REFERENCE TO RELATED APPLICATIONS

This application claims the priority benefit of French Patent Application No. 2312182, filed on Nov. 9, 2023, entitled “Procédé de fabrication d′un dispositive photonique,” which is hereby incorporated herein by reference to the maximum extent allowable by law.

### TECHNICAL FIELD

The present description generally concerns the field of photonics, and more particularly photonic components. The present disclosure more specifically relates to a photonic component and to its manufacturing method.

### BACKGROUND

A photonic component is a component enabling the generation, the transmission, the processing, or the conversion of optical signals. A photonic component may further be adapted to process electrical signals, such as for example, for the conversion of an optical signal into an electronic signal, or conversely.

Certain photonic component manufacturing methods may use techniques known and used for the manufacturing of electronic components, such as for example microelectronics techniques.

It would be desirable to be able to improve, at least partly, certain aspects of known photonic devices and/or components, and in particular certain aspects of known photonic component manufacturing methods.

### SUMMARY

There exists a need for higher-performance photonic devices and/or components.

There exists a need for higher-performance methods of manufacturing a photonic component.

An embodiment overcomes all or part of the disadvantages of known photonic components.

An embodiment overcomes all or part of the disadvantages of known methods of manufacturing a photonic component.

An embodiment provides a method of manufacturing a photonic device comprising the following successive steps: forming on a first substrate at least one metallization level, and a first bonding layer, forming on a second high-resistivity substrate a second bonding layer adapted to cooperate with the first bonding layer, bonding the first bonding layer to the second bonding layer, removing the first substrate, and forming a first optical component on a first surface of the at least one metallization level opposite to a second surface of the at least one metallization level in contact with the first bonding layer.

A sum of the thicknesses of the first and second bonding layers and of the thickness of the at least one metallization level is greater than 3 μm.

According to an embodiment, the sum is greater than 4 μm.

According to an embodiment, the first bonding layer is made of silicon oxide, and the second bonding layer is made of silicon oxide.

According to an embodiment, the second high-resistivity substrate is a semiconductor substrate.

According to an embodiment, the second high-resistivity substrate has a resistivity greater than 500 Ohms-cm.

According to an embodiment, the second high-resistivity substrate has a resistivity greater than 700 Ohms-cm.

According to an embodiment, the first optical component is a waveguide, or a waveguide adapted to being coupled to an optical fiber, or a waveguide adapted to being coupled to a broadband optical fiber.

According to an embodiment, the at least one metallization level comprises at least one first electronic, optical, or optoelectronic component.

According to an embodiment, the at least one metallization level is adapted to being electrically coupled by a via having the first optical component formed therein.

According to an embodiment, the method comprises, during the step of forming of the first component, a step of forming of a third layer on the first surface of the at least one metallization level.

According to an embodiment, the third layer is made of a material selected from the group comprising: indium phosphide (InP), a material comprising indium phosphide (InP), indium gallium arsenide (InGaAs), a material comprising indium gallium arsenide (InGaAs), aluminum gallium arsenide (AlGaAs), a material comprising aluminum gallium arsenide (AlGaAs), indium gallium arsenide phosphide (InGaAsP), a material comprising indium gallium arsenide phosphide (InGaAsP), lithium niobate (LiNbO₃), a material comprising lithium niobate (LiNbO₃), barium titanate (BaTiO₃), a material comprising barium titanate (BaTiO₃), or the third layer is a multiple quantum well stack, comprising layers made of materials from the following group: indium phosphide (InP), doped indium phosphide (InP), for example, N-type or P-type doped, indium gallium arsenide (InGaAs), doped indium gallium arsenide (InGaAs), for example N-type doped or P-type doped, aluminum indium gallium arsenide (AlInGaAs), indium gallium arsenide (InGaAs), and indium gallium arsenide phosphide (InGaAsP). In this case, photonic component 300 may be a laser.

According to an embodiment, the first component is selected from the group comprising: a semiconductor-insulator-semiconductor capacitor modulator, a photodiode, a phototransistor, a laser, and a Pockels-effect modulator.

According to an embodiment, the at least one metallization level is formed on a front surface of the first substrate.

According to an embodiment, at least one second optical component is formed on a rear surface of the second substrate.

According to an embodiment, the at least one second optical component is a waveguide.

Another embodiment provides a photonic device comprising a first optical component arranged on a stack successively comprising: a first surface of at least one metallization level, a first bonding layer, a second bonding layer, and a second high-resistivity substrate, wherein a sum of the thicknesses of the first and second bonding layers and of the thickness of the at least one metallization level is greater than 3 μm.

According to an embodiment, this sum is on the order of 4 μm.

According to an embodiment, the second high-resistivity substrate has a resistivity greater than 500 Ohms-cm.

According to an embodiment, the first optical component is a waveguide.

According to an embodiment, the previously-described photonic device is obtained by the previously-described method.

According to an embodiment, the at least one metallization level is formed on a front surface of the first substrate.

According to an embodiment, at least one second optical component is formed on a rear surface of the second substrate.

According to an embodiment, the at least one second optical component is a waveguide.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a cross-section view of an embodiment of a photonic component;

FIG. 2 shows a cross-section view of a step of an implementation mode of a method of manufacturing the photonic component of FIG. 1;

FIG. 3 shows a cross-section view of another step of an implementation mode of a method of manufacturing the photonic component of FIG. 1;

FIG. 4 shows a cross-section view of another step of an implementation mode of a method of manufacturing the photonic component of FIG. 1;

FIG. 5 shows a cross-section view of another step of an implementation mode of a method of manufacturing the photonic component of FIG. 1;

FIG. 6 shows a cross-section view of another step of an implementation mode of a method of manufacturing the photonic component of FIG. 1;

FIG. 7 shows a cross-section view of another step of an implementation mode of a method of manufacturing the photonic component of FIG. 1;

FIG. 8 shows a cross-section view of another step of implementation mode of a method of manufacturing the photonic component of FIG. 1;

FIG. 9 shows a cross-section view of another step of an implementation mode of a method of manufacturing the photonic component of FIG. 1;

FIG. 10 shows a cross-section view of another step of implementation mode of a method of manufacturing the photonic component of FIG. 1;

FIG. 11 shows a cross-section view of another step of implementation mode of a method of manufacturing the photonic component of FIG. 1; and

FIG. 12 shows a cross-section view of another embodiment of a photonic component.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “on the order of” signify plus or minus 10%, preferably of plus or minus 5%.

The embodiments and implementation modes described hereafter concern a photonic device and its manufacturing method.

According to an embodiment, this photonic device is a coupling device enabling to receive one or a plurality of optical signals transmitted by an optical fiber. This device is, further, more particularly adapted to receive one or a plurality of optical signals transmitted by a broadband optical fiber, having for example a minimum bandwidth of 100 nm, for example in the range from 1,310 to 1,550 nm.

Known photonic devices have disadvantages regarding broadband optical fibers, and in particular for problems of material index matching between the materials of the optical fiber and the materials of the photonic device. Such matching problems can result in a degradation of the signal received from the optical fiber.

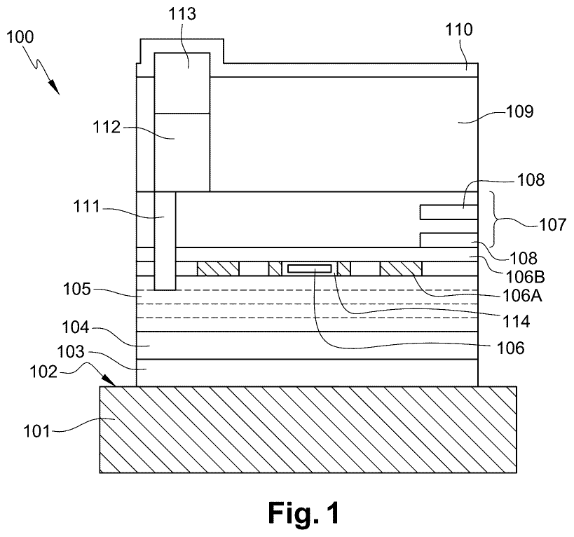

The photonic device according to the embodiment provides overcoming this problem, and, further, increasing the transmission rate of data received from the optical fiber. To achieve this, the electronic device comprises one or a plurality of high-performance electronic circuits, or even microelectronic circuits, formed inside and on top of a semiconductor substrate. The device then comprises a waveguide receiving the signal(s) from the broadband optical fiber and a high-resistivity semiconductor substrate allowing the implementation of such electronic circuits. There is here called “high-resistivity substrate” a semiconductor substrate having a resistivity greater than 500 Ohms-cm, preferably greater than 700 Ohms-cm, or sometimes greater than 1 kOhm·cm. To optically insulate the waveguide from the substrate, the photonic device comprises, according to an embodiment, a very thick optically-insulating device, that is, having a thickness greater than 3 μm, arranged between the waveguide and the substrate. Such an embodiment of a photonic device is described in relation with FIG. 1.

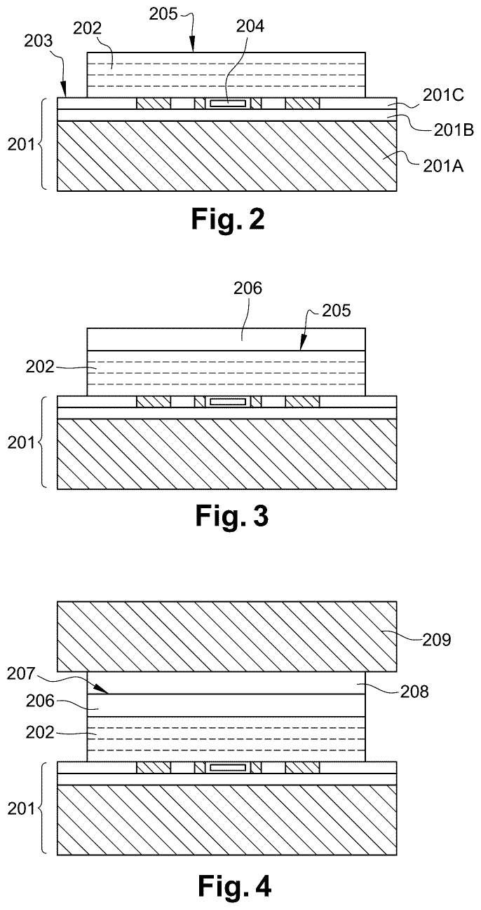

A method of manufacturing such a photonic device overcomes the conventional disadvantages of electronic, microelectronic, and/or photonic component manufacturing techniques, and in particular, overcomes the disadvantages that can arise from the use of a photonic device such as previously defined. Such an implementation mode of a photonic device manufacturing method is described in relation with FIGS. 2 to 11.

FIG. 1 is a cross-section view of an embodiment of a photonic component 100.

As previously described, photonic component 100 is formed inside, on top of, and/or from a highly-resistive semiconductor substrate 101, that is, a substrate having a resistivity greater than 500 Ohms-cm, for example, preferably greater than 700 Ohms-cm, or sometimes greater than 1 kOhm·cm. According to an example, the resistivity of substrate 101 is on the order of 780 Ohms-cm. According to an example, substrate 101 is a silicon substrate.

On a surface 102 of substrate 101, there rests an optically and electrically insulating layer 103. Layer 103 is also used as a bonding layer in the method of manufacturing device 100. According to an example, layer 103 is a silicon oxide layer. When referring to a bonding layer, it should be understood that it can be a bonding layer, a fixing layer or a layer allowing one material to adhere to another.

On a rear surface of substrate 101, opposite to surface 102, there may be formed one or a plurality of optical components, such as waveguides. These components are not shown in FIG. 1.

On layer 103, there rests another optically and electrically insulating layer 104. Layer 104 is also used as a bonding layer in the method of manufacturing device 100. According to an embodiment, layer 104 is a bonding layer adapted to cooperate with layer 103. According to an example, layer 104 is a silicon oxide layer.

According to an example, the sum of the thicknesses of layers 103 and 104 is greater than 2 μm, for example on the order of 4 μm.

On layer 104, there rests one or a plurality of metallization levels 105 adapted to comprise one or a plurality of electronic, optical, or optoelectronic devices 106 of photonic device 100. According to an example, device(s) 106 may comprise passive photonic components such as waveguides, and/or active photonic components such as modulators, photodiodes. An active photonic component can be assimilated to an optoelectronic component. According to another example, device 106 may be a modulator, a radiator, etc. Device(s) 106 may be formed inside and/or on top of a semiconductor substrate, such as a silicon (Si) or germanium (Ge) substrate. Each device 106 may also be laterally surrounded by a layer 114 of an electrically and/or optically insulating material, such as silicon oxide, to electrically and optically insulate it from other devices.

Component(s) 106 are, for example, formed from a substrate of silicon on insulator (SOI) type, a semiconductor layer 106A, or portions of this layer as shown in FIG. 1, may remain on top of component(s) 106. Similarly, an insulating layer 106B of the substrate, also called buried oxide (BOx) layer, rests on semiconductor layer 106A.

The first metallization level is symbolized in FIG. 1 by the placing of device 106. According to an example, device 100 comprises three metallization levels. According to an embodiment, metallization level(s) 105 are considered as optically insulating. Indeed, metallization levels 105 comprise metal tracks manufactured in layers of dielectric material, these tracks are, for example, obtained via methods of photoetching/growth of a metal, preferably copper, followed by a planarization method. Only the dielectric portions are “insulators” from an optical viewpoint, while the metal tracks absorb optical signals.

According to an embodiment, the sum of the thicknesses of layers 103 and 104 and of the thickness of the metallization level(s) is greater than 3 μm, for example greater than 4 μm.

On metallization level(s) 105, there rests a layer 107, having an optical component 108 forming the waveguide formed therein. According to an example, layer 107 is a silicon oxide layer, and optical component 108 is made of silicon nitride (SiN). According to an example, layer 107 has a thickness greater than 1 μm, for example on the order of 1.5 μm. Thus, optical component 108 is separated from resistive substrate 101 by a stack comprising: optically-insulating layer 103, optically-insulating layer 104, metallization level(s) 105 considered as optically insulating, and insulating layer 114 surrounding device(s) 106.

As previously mentioned, the thickness of this stack is greater than 3 μm, for example greater than 4 μm.

According to an embodiment, the optical component is adapted to being coupled to a broadband optical fiber, for example having a minimum bandwidth of 100 nm, for example in the range from 1,310 to 1,550 nm.

On layer 107 are formed layers enabling to form electric contacts of device 100. In particular, an electrically-insulating layer 109 covered by a passivation layer 110. According to an example, layer 109 is a silicon oxide layer, having a thickness greater than 4 μm, for example on the order of 5.3 μm. According to an example, passivation layer 110 is formed of a stack of a silicon oxide layer and of a silicon nitride layer, and has a thickness in the range from 1 to 3 μm.

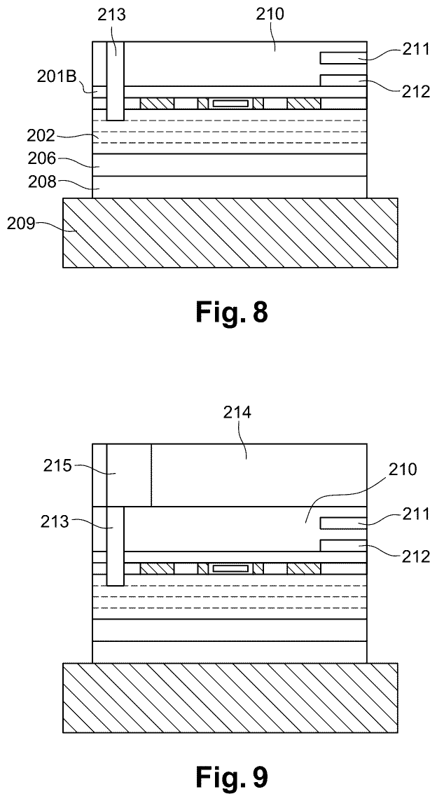

A contact may be formed in photonic device 100. For this purpose, a first conductive via 111 is formed through layer 107 and down to one of the metallization levels of metallization level(s) 105. A conductive track 112 may be formed in layer 109 and in contact with first conductive via 111. According to an example, conductors 111 and 112 are made of a metal or of a metal alloy. According to an example, the material of conductors 111 and 112 comprises copper and/or a copper alloy. A contact 113 is then formed through layer 109 and passivation layer 110 to join conductor 112. The forming of conductors 111, 112, and 113 is described in detail in relation with FIGS. 8 to 11. According to an example, the contact is made of a metal or of a metal alloy. According to an example, the material of contact 113 comprises aluminum and/or an alloy comprising aluminum.

FIGS. 2 to 11 are cross-section views illustrating devices after steps of an implementation mode of a method of manufacturing a photonic component of the type of the photonic component 100 described in relation with FIG. 1.

At the step of FIG. 2, a semiconductor substrate 201, for example a substrate of silicon on insulator (SOI) type, is used to form one or a plurality of metallization levels 202 from its upper surface 203. Substrate 201 is formed of a semiconductor substrate 201A having a stack of an electrically-insulating layer 201B and of a semiconductor layer 201C resting thereon. Insulating layer 201B is also known as a buried oxide (BOX) layer. Metallization level(s) 202 are of the type of the metallization level(s) 105 described in relation with FIG. 1, and comprise at least one electronic component 204 of the type of the component(s) 106 described in relation with FIG. 1. As in FIG. 1, the first metallization level of metallization level(s) 202 is symbolized by the placing of component 204. In other words, in FIG. 2, the first metallization level is on the side of surface 203 of metallization levels 202, opposite to another surface 205 of metallization levels 202. Further, as in FIG. 1, component 204 is surrounded by an insulating layer, not shown in FIGS. 2 to 11.

Metallization levels 202 and component 204 are thus formed on a front surface of substrate 201.

At the step of FIG. 3, successive to the step of FIG. 2, a first bonding layer 206 of the type of the insulating layer 104 described in relation with FIG. 1 is deposited on surface 205 of metallization level(s) 202. According to one example, layer 206 is a silicon oxide layer.

At the step of FIG. 4, successive to the step of FIG. 3, a second bonding layer 208 is used to bond a high-resistivity substrate 209 to the structure obtained in FIG. 3. More particularly, substrate 209 is a substrate of the type of the substrate 101 described in relation with FIG. 1, that is, a semiconductor substrate having a resistivity greater than 500 Ohms-cm, for example, preferably greater than 700 Ohms-cm, or sometimes greater than 1 kOhm·cm. According to an example, the resistivity of substrate 209 is on the order of 780 Ohms-cm. According to an example, substrate 209 is a silicon substrate. Further, bonding layer 208 is of the type of the insulating layer 103 described in relation with FIG. 1. According to an embodiment, layer 208 is a bonding layer adapted to cooperate with bonding layer 206. According to an example, bonding layer is a silicon oxide layer.

To implement the step of FIG. 4, bonding layer 208 is formed on a surface of substrate 209. A free surface of bonding layer 208, opposite to substrate 209, is then bonded to bonding layer 206, for example, by using a molecular bonding method.

Further, as previously mentioned, the sum of the thicknesses of layers 206 and 208 is greater than 2 μm, for example on the order of 4 μm. Further, according to an embodiment, the sum of the thicknesses of layers 206 and 208 and of the thickness of metallization level(s) 202 is greater than 4 μm, for example greater than 5 μm.

At this step, optical components may be formed on the rear surface of substrate 209, that is, the surface which is not covered by bonding layer 208.

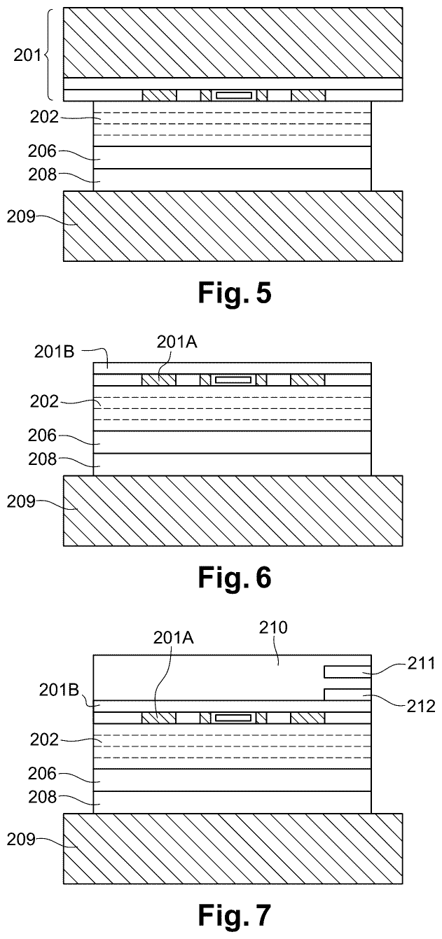

At the step of FIG. 5, successive to the step of FIG. 4, the structure obtained at step 4 is turned upside down. Thus, the first metallization level of metallization level(s) 202 is on the high side of FIG. 5. Further, the entire structure rests on high-resistivity substrate 209.

At the step of FIG. 6, successive to the step of FIG. 5, substrate 201A is removed from the structure obtained in FIG. 5. According to an example, substrate 201A is removed by using a method combining a grinding step and a chemical removal step.

At the step of FIG. 7, successive to the step of FIG. 6, an optical component, of the type of the optical component 108 of FIG. 1, is formed on buried oxide layer 201B. For this purpose, a first layer 212 may be formed by a photolithography process and then etched to obtain the desired shape. A first portion of an insulating layer 210, for example made of silicon oxide, is then formed on layer 212, for example, by deposition and then chemical planarization. A second layer 211 may be formed on the first portion of layer 210, for example, by using a photolithography process and then an etching process. A second portion of insulating layer 210 may then be formed to cover layer 211. The assembly of layers 210 to 212 may enable, for example, to form an optical fiber, or other waveguide-type passive components allowing the coupling to an external optical fiber (not shown).

At the step of FIG. 8, successive to the step of FIG. 7, a first portion of a contacting area is formed. Thus, a conductive via 213 thoroughly crossing layer 210, insulating layer 201B, layer 201C, and a portion of metallization level(s) 202, is formed. Conductive via 213 thus extends between an upper surface of layer 210 and down to a metallization level of metallization level(s) 202. Conductive via 213 is of the type of the conductive via 111 described in relation with FIG. 1. In other words, conductive via 213 is made of a metal or of a material comprising metal, for example copper or an alloy comprising copper. For this purpose, methods of deposition, photolithography, etching, and planarization may here be implemented.

At the step of FIG. 9, successive to the step of FIG. 8, an electrically-insulating layer 214 is formed on layer 210. According to an example, insulating layer 214 is a silicon oxide layer having a thickness greater than 2 μm, for example on the order of 2.8 μm.

Further, at the step of FIG. 9, a second portion of the contacting area is formed. Thus, a conductive track 215 thoroughly crossing layer 214 is formed. Conductive track 215 thus extends between an upper surface of layer 210, and is in contact with via 213. Conductive track 215 is of the type of the conductive track 112 described in relation with FIG. 1. In other words, conductive via 215 is made of a metal or a material comprising metal, such as copper or an alloy comprising copper. For this purpose, methods of deposition, photolithography, etching, and planarization may here be implemented.

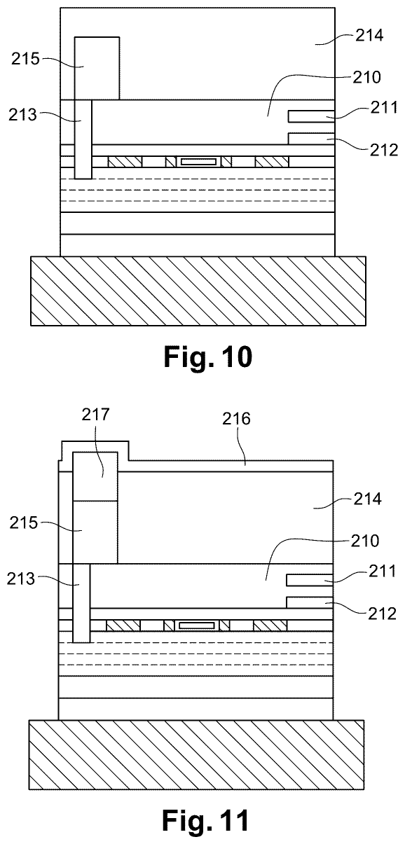

At the step of FIG. 10, successive to the step of FIG. 9, the thickness of electrically-insulating layer 214 is increased to fully cover conductive via 215. At this step, layer 214 is of the same type as the layer 109 described in relation with FIG. 1. Thus, according to an example, layer 109 is a silicon oxide layer, having a thickness greater than 4 μm, for example on the order of 5.3 μm.

At the step of FIG. 11, successive to the step of FIG. 10, once contact 215 has been formed, a contact 217 of the type of the contact 113 described in relation with FIG. 1 is formed. For this purpose, an insulating layer, for example made of silicon oxide, is deposited. According to an example, this insulating layer has a thickness on the order of 0.6 μm. Photolithography and etching steps are then implemented to form a cavity in layer 214 and in layer 216 above via 215. This cavity is then filled with a layer made of a material forming contact 217, for example a metal or metal alloy, for example aluminum or an alloy comprising aluminum. According to an example, this layer has a thickness on the order of 1.5 μm.

Further, at the step of FIG. 11, an operation of passivation of layer 214 is implemented. For this purpose, a passivation layer 216 is formed on the accessible surface of layer 214. According to an example, the passivation layer is formed of a silicon oxide layer, having a thickness on the order of 2 μm, and of a nitride oxide layer, having a thickness on the order of 0.6 μm. Photolithography and etching steps are then implemented to make the contact accessible, or to facilitate the assembling of the device.

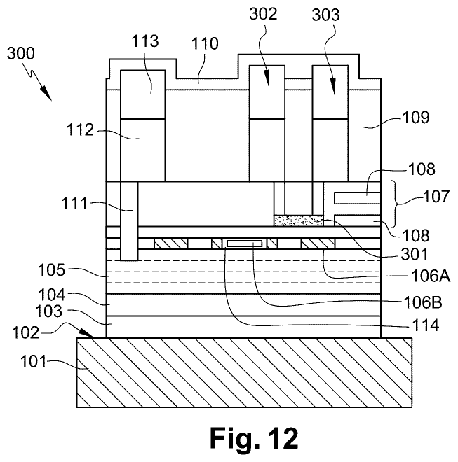

FIG. 12 is a cross-section view of an embodiment of a photonic component 300.

Photonic component 300 is similar to the component 100 described in relation with FIG. 1. The elements identical to the components are not described again in detail here. Only the differences between them are highlighted hereafter.

Thus, photonic component 300 comprises all the elements of component 100, but also comprises a layer 301 made of a material M arranged in layer 107, preferably on an upper surface of metallization levels 105. According to a variant, layer 301 may be a stack of layers.

According to a preferred embodiment, layer 301 is arranged directly in alignment with electronic device(s) 106 to be able to achieve, for example, optical couplings. Similarly, optical component 108 and device(s) 106 may also be aligned, at least partially, to also achieve optical couplings.

According to a first example, material M is indium phosphide (InP), or comprises indium phosphide (InP). In this case, photonic component 300 may be a semiconductor-insulator-semiconductor capacitor modulator, or SISCAP modulator.

According to a second example, material M is indium gallium arsenide (InGaAs), or comprises indium gallium arsenide (InGaAs). In this case, photonic component 300 may be a photodiode and/or a phototransistor.

According to a third example, material M is aluminum gallium arsenide (AlGaAs), or comprises aluminum gallium arsenide (AlGaAs). In this case, photonic component 300 may be a photonic component allowing the generation of an electron pair, and/or allowing the generation of light such as a laser.

According to a fourth example, material M is indium gallium arsenide phosphide (InGaAsP), or comprises indium gallium arsenide phosphide (InGaAsP). In this case, photonic component 300 may be a semiconductor-insulator-semiconductor capacitor modulator, or a photodiode.

According to a fifth example, material M is lithium niobate (LiNbO₃) or comprises lithium niobate (LiNbO₃). In this case, photonic component 300 may be a Pockels effect modulator.

According to a sixth example, material M is barium titanate (BaTiO₃) or comprises barium titanate (BaTiO₃). In this case, photonic component 300 may be a Pockels effect modulator.

According to a seventh example, layer 301 is a multiple quantum well (MQW) stack. According to an example, such a stack may comprise layers made of materials from the following group: indium phosphide (InP), doped indium phosphide (InP), for example N-type or P-type doped, gallium indium arsenide (InGaAs), doped gallium indium arsenide (InGaAs), for example N-type or P-type doped, aluminum indium gallium arsenide (AlInGaAs), gallium indium arsenide (InGaAs), and indium gallium arsenide phosphide (InGaAsP). In this case, photonic component 300 may be a laser.

Photonic component 300 may further comprise one or a plurality of contacting areas 302 and/or 303 enabling to establish an electrical contact with layer 301. According to an embodiment, contacting areas 302 and/or 303 are formed in the same way as the contacting area formed by conductors 111 and 112 and contact 113.

The method of manufacturing photonic component 300 is similar to the method of manufacturing photonic component 100, but additionally comprises a step of forming of layer 301 and, if necessary, of etching or of structuring of layer 301 between the step described in relation with FIG. 6 and the step described in relation with FIG. 7.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

What is claimed:

1. A method of manufacturing a photonic device, the method comprising, successively:
forming on a first substrate at least one metallization level, and a first bonding layer;
forming on a second high-resistivity substrate a second bonding layer;
bonding the first bonding layer to the second bonding layer;
removing the first substrate; and
forming a first optical component on a first surface of the at least one metallization level opposite to a second surface of the at least one metallization level in contact with the first bonding layer, a sum of thicknesses of the first bonding layer, the second bonding layer, and the at least one metallization level being greater than 3 μm.

2. The method according to claim 1, wherein the sum is greater than 4 μm.

3. The method according to claim 1, wherein:
the first bonding layer is silicon oxide, and
the second bonding layer is silicon oxide.

4. The method according to claim 1, wherein the second high-resistivity substrate is a semiconductor substrate.

5. The method according to claim 1, wherein the second high-resistivity substrate has a resistivity greater than 500 Ohms-cm.

6. The method according to claim 5, wherein the second high-resistivity substrate has a resistivity greater than 700 Ohms-cm.

7. The method according to claim 1, wherein the first optical component is a waveguide, or a waveguide configured to couple to an optical fiber, or a waveguide configured to couple to a broadband optical fiber.

8. The method according to claim 1, wherein the at least one metallization level comprises at least one first electronic, optical, or optoelectronic component.

9. The method according to claim 1, wherein the at least one metallization level is electrically coupled to a via crossing a layer having the first optical component formed therein.

10. The method according to claim 1, comprising, during the forming of the first optical component, forming a third layer on the first surface of the at least one metallization level.

11. The method according to claim 10, wherein:
the third layer is selected from the group consisting of: indium phosphide (InP), a material comprising indium phosphide (InP), indium gallium arsenide (InGaAs), a material comprising indium gallium arsenide (InGaAs), aluminum gallium arsenide (AlGaAs), a material comprising aluminum gallium arsenide (AlGaAs), indium gallium arsenide phosphide (InGaAsP), a material comprising indium gallium arsenide phosphide (InGaAsP), lithium niobate (LiNbO₃), a material comprising lithium niobate (LiNbO₃), barium titanate (BaTiO₃), or a material comprising barium titanate (BaTiO₃); or
the third layer is a multiple quantum well stack, comprising layers of materials selected from the group consisting of: indium phosphide (InP), doped indium phosphide (InP), N-type or P-type doped indium gallium arsenide (InGaAs), doped indium gallium arsenide (InGaAs), N-type or P-type doped aluminum indium gallium arsenide (AlInGaAs), indium gallium arsenide (InGaAs), or indium gallium arsenide phosphide (InGaAsP).

12. The method according to claim 10, wherein the first optical component is selected from the group consisting of: a semiconductor-insulator-semiconductor capacitor modulator, a photodiode, a phototransistor, a laser, or a Pockels effect modulator.

13. The method according to claim 1, wherein the at least one metallization level is formed on a front surface of the first substrate.

14. The method according to claim 1, wherein at least one second optical component is formed on a rear surface of the second high-resistivity substrate.

15. The method according to claim 14, wherein the at least one second optical component is a waveguide.

16. A photonic device comprising:
a first optical component disposed on a stack; and
the stack, successively comprising:
a first surface of at least one metallization level;
a first bonding layer;
a second bonding layer; and
a second high-resistivity substrate;
wherein a sum of thicknesses of the first bonding layer, the second bonding layer, and the at least one metallization level is greater than 3 μm.

17. The photonic device according to claim 16, wherein the sum is on an order of 4 μm.

18. The photonic device according to claim 16, wherein the second high-resistivity substrate has a resistivity greater than 500 Ohms-cm.

19. The photonic device according to claim 16, wherein the first optical component is a waveguide.

20. The photonic device according to claim 16, wherein the first optical component is disposed on the first surface of the at least one metallization level opposite to a second surface of the at least one metallization level in contact with the first bonding layer.

21. The photonic device according to claim 20, wherein the first optical component is disposed in an insulating layer disposed on the first surface of the at least one metallization level.

22. The photonic device according to claim 16, wherein at least one second optical component is disposed on a rear surface of the second high-resistivity substrate.

23. The photonic device according to claim 22, wherein the at least one second optical component is a waveguide.
